(19) United States
(12) Patent Application Publication
(10) Pub. No.: US 2017/0040318 A1
(43) Pub. Date: Feb. 9, 2017

(54) SEMICONDUCTOR DEVICE AND METHOD FOR FABRICATING THE SAME

(71) Applicant: United Microelectronics Corp., Hsin-Chu City (TW)

(72) Inventors: Yu-Hsiang Hung, Tainan City (TW); Chih-Kai Hsu, Tainan City (TW); Chao-Hung Lin, Changhua County (TW); Ssu-I Fu, Kaohsiung City (TW); Jyh-Shyang Jenq, Pingtung County (TW)

(21) Appl. No.: 14/842,855

(22) Filed: Sep. 2, 2015

(30) Foreign Application Priority Data
Aug. 3, 2015 (TW) 104125042

(51) Int. Cl. H01L 27/088; H01L 29/06; H01L 29/45; H01L 21/8234

(52) U.S. Cl. CPC H01L 27/0886; H01L 21/823431; H01L 21/823475; H01L 21/823462; H01L 21/823437; H01L 29/0649; H01L 29/45

(57) ABSTRACT

A method for fabricating semiconductor device is disclosed. The method includes the steps of: providing a substrate having a first fin-shaped structure on a first region and a second fin-shaped structure on a second region; forming a plurality of first gate structures on the first fin-shaped structure, a plurality of second gate structures on the second fin-shaped structure, and an interlayer dielectric (ILD) layer around the first gate structures and the second gate structures; forming a first patterned mask on the ILD layer; forming a second patterned mask on the second region; using the first patterned mask and the second patterned mask to remove all of the ILD layer from the first region and part of the ILD layer from the second region for forming a plurality of first contact holes in the first region and a plurality of second contact holes in the second region.

### BACKGROUND OF THE INVENTION

1. Field of the Invention

The invention relates to a method for fabricating semiconductor device, and more particularly, to a method of using multiple patterned masks to form gate structures of different pitches on a substrate.

2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However, the approach of using etching process to remove the hard mask from gate structure on the edge of fin-shaped structure in current FinFET process and also forming contact holes typically results in uneven openings affecting the formation of contact plugs thereafter and the performance of the device. Hence, how to improve the current process to resolve this issue has become an important task in this field.

### SUMMARY OF THE INVENTION

According to a preferred embodiment of the present invention, a method for fabricating semiconductor device is disclosed. The method includes the steps of: providing a substrate having a first fin-shaped structure on a first region and a second fin-shaped structure on a second region; forming a plurality of first gate structures on the first fin-shaped structure, a plurality of second gate structures on the second fin-shaped structure, and an interlayer dielectric (ILD) layer around the first gate structures and the second gate structures; forming a first patterned mask on the ILD layer and between the first region and the second region; forming a second patterned mask on the second region; using the first patterned mask and the second patterned mask to remove all of the ILD layer from the first region and part of the ILD layer from the second region for forming a plurality of first contact holes in the first region and a plurality of second contact holes in the second region.

According to another aspect of the present invention, a semiconductor device is disclosed. The semiconductor device includes: a substrate having a first region and a second region; a first fin-shaped structure on the substrate and a second fin-shaped structure on the second region; a plurality of first gate structures on the first fin-shaped structure, wherein the first gate structures comprise no interlayer dielectric (ILD) layer therebetween; and a plurality of second gate structures on the second fin-shaped structure, wherein the second gate structures comprise a ILD layer therebetween.

According to another aspect of the present invention, a semiconductor device is disclosed. The semiconductor device includes: a substrate having a fin-shaped structure thereon; a plurality of first gate structures on the fin-shaped structure and an interlayer dielectric (ILD) layer around the first gate structures; a first contact plug in the ILD layer adjacent to the first gate structures; a first dielectric layer on the ILD layer; a second contact plug in the first dielectric layer and contacting the first contact plug; a second dielectric layer on the first dielectric layer; a third contact plug in the second dielectric layer and contacting the second contact plug; and a fourth contact plug in the second dielectric layer and the first dielectric layer and electrically connected to one of the first gate structures.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate a method for fabricating semiconductor device according to a preferred embodiment of the present invention.

FIGS. 9-10 illustrate a method of fabricating semiconductor device according to another embodiment of the present invention.

### DETAILED DESCRIPTION

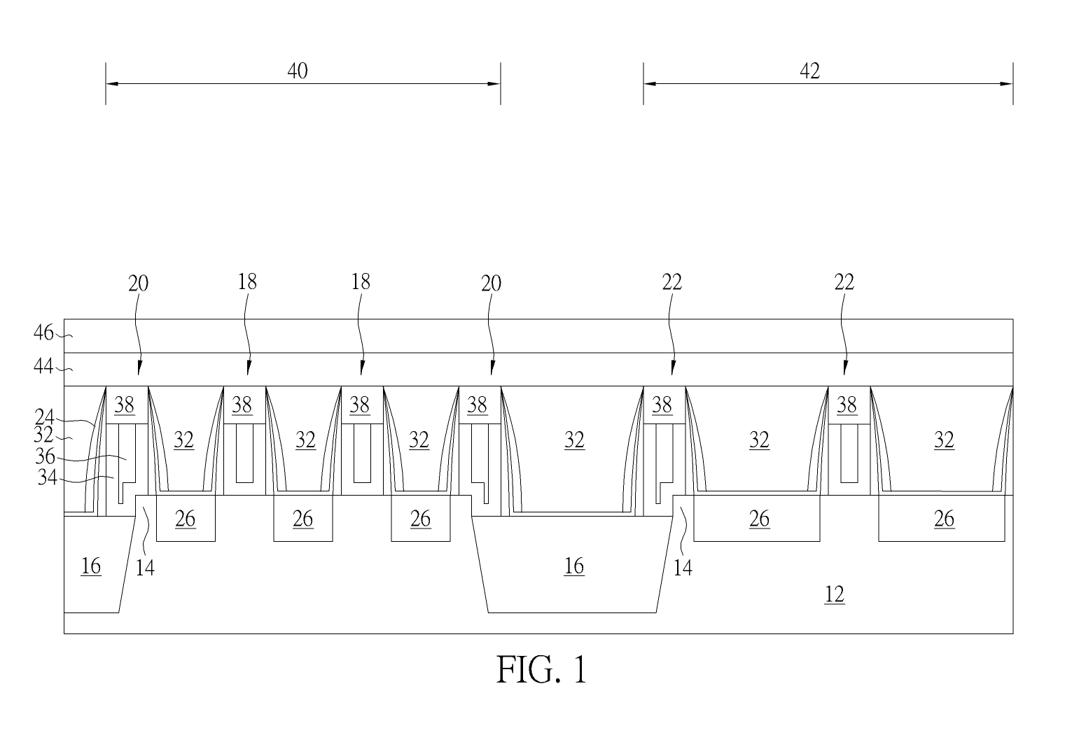

Referring to FIGS. 1-8, FIGS. 1-8 illustrate a method for fabricating semiconductor device according to a preferred embodiment of the present invention. It should be noted despite this embodiment pertains to a non-planar MOS transistor, the method of the present invention could be applied to either planar or non-planar transistor devices depending on the demand of the product. As shown in FIG. 1, a substrate 12, such as a silicon substrate or silicon-on-insulator (SOI) substrate is provided and a first region 40 and a second region 42 are defined on the substrate 12. Preferably, the first region 40 is used for fabricating gate structures with smaller gaps or pitches in the later process while the second region 42 is used for fabricating gate structures with larger gaps or pitches afterwards. A fin-shaped structure 14 is then formed on the substrate 12 of the first region 40 and another fin-shaped structure 14 is formed on the substrate 12 of the second region 42, in which the bottom of the fin-shaped structures 14 is enclosed by a shallow trench isolation (STI) preferably composed of an insulating layer such as silicon oxide. Next, a plurality of structures 18 and 20 are formed on the fin-shaped structure 14 on first region 40 and a plurality of gate structures 22 are formed on the fin-shaped structures 14 on second region 42, in which the gate structures 20 on first region 40 are disposed on the edges of the fin-shaped structure 14 while sitting on the fin-shaped structure 14 and the STI 16 at the same time.

The formation of the fin-shaped structure 14 could be accomplished by first forming a patterned mask (now shown) on the substrate, 12, and an etching process is performed to transfer the pattern of the patterned mask to the substrate 12. Next, depending on the structural difference of a tri-gate transistor or dual-gate fin-shaped transistor being fabricated, the patterned mask could be stripped selectively or retained, and deposition, chemical mechanical polishing (CMP), and etching back processes are carried out to form a STI 16 surrounding the bottom of the fin-shaped structure 14. Alternatively, the formation of the fin-shaped structure 14 could also be accomplished by first forming a patterned hard mask (not shown) on the substrate 12, and then performing an epitaxial process on the exposed substrate 12 through the patterned hard mask to grow a semiconductor layer. This semiconductor layer could then be used as the corresponding fin-shaped structure 14. Similarly, the patterned hard mask could be removed selectively or retained, and deposition, CMP, and then etching back could be used to form a STI 16 surrounding the bottom of the fin-shaped structure 14. Moreover, if the substrate 12 were a SOI substrate, a patterned mask could be used to etch a semiconductor layer on the substrate until reaching a bottom oxide layer underneath the semiconductor layer to form the corresponding fin-shaped structure. If this means were chosen the aforementioned steps for fabricating the STI 16 could be eliminated.

The fabrication of the gate structures 18, 20, 22 could be accomplished by a gate first process, a high-k first approach from gate last process, or a high-k last approach from gate last process. Since this embodiment pertains to a high-k first approach, dummy gates (not shown) composed of high-k dielectric layer and polysilicon material could be first formed on the fin-shaped structures 14 and the STI 16, and a spacer 24 is formed on the sidewall of each dummy gate. A source/drain region 26 and epitaxial layer (not shown) are then formed in the fin-shaped structures 14 and/or substrate 12 adjacent to two sides of the spacer 24, a selective contact etch stop layer (CESL) (not shown) is formed on the dummy gates, and an interlayer dielectric (ILD) layer 32 composed of tetraethyl orthosilicate (TEOS) is formed on the CESL. In this embodiment, the spacer 24 if preferably a composite spacer composed of oxide-nitride-oxide, but not limited thereto.

Next, a replacement metal gate (RMG) process could be conducted to planarize part of the ILD layer 32 and then transforming the dummy gate into metal gates 18, 20, 22. The RMG process could be accomplished by first performing a selective dry etching or wet etching process, such as using etchants including ammonium hydroxide (NH₄OH) or tetramethylammonium hydroxide (TMAH) to remove the polysilicon material from dummy gates for forming recesses (not shown) in the ILD layer 32. Next, a conductive layer including at least a U-shaped work function metal layer 34 and a low resistance metal layer 36 is formed in the recesses, and a planarizing process is conducted thereafter so that the surface of the U-shaped work function metal layer 34 and low resistance metal layer 36 is even with the surface of the ILD layer 32.

In this embodiment, the work function metal layer 34 is formed for tuning the work function of the later formed metal gates to be appropriate in an NMOS or a PMOS. For an NMOS transistor, the work function metal layer 34 having a work function ranging between 3.9 eV and 4.3 eV may include titanium aluminide (TiAl), zirconium aluminide (ZrAl), tungstenaluminide (WAl), tantalumaluminide (TaAl), hafnium aluminide (HfAl), or titanium aluminum carbide (TiAlC), but it is not limited thereto. For a PMOS transistor, the work function metal layer 34 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 34 and the low resistance metal layer 36, in which the material of the barrier layer may include titanium (Ti), titanium nitride (TiN), tantalum (Ta) or tantalum nitride (TaN). Furthermore, the material of the low-resistance metal layer 36 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity.

Next, part of the work function metal layer 34 and low resistance metal layer 36 could be removed, and a hard mask 38 is formed on the work function metal layer 34 and the low resistance metal layer 36 to form the gate structure 18, 20, 22. The hard mask 38 could be a single material layer or composite material layer, such as a composite layer containing both silicon oxide and silicon nitride.

Next, a cap layer 44 is covered entirely on the gate structures 18, 20, 22 and the ILD layer 32 and a mask layer 46 is formed on the cap layer 44 thereafter. In this embodiment, the cap layer 44 is preferably used as a pre-metal dielectric (PMD) layer, in which the cap layer 44 and the ILD layer 32 could be composed of same material or different material. The cap layer 44 is preferably composed of material such as silicon oxide. The mask layer 46 is preferably a metal mask composed of TiN.

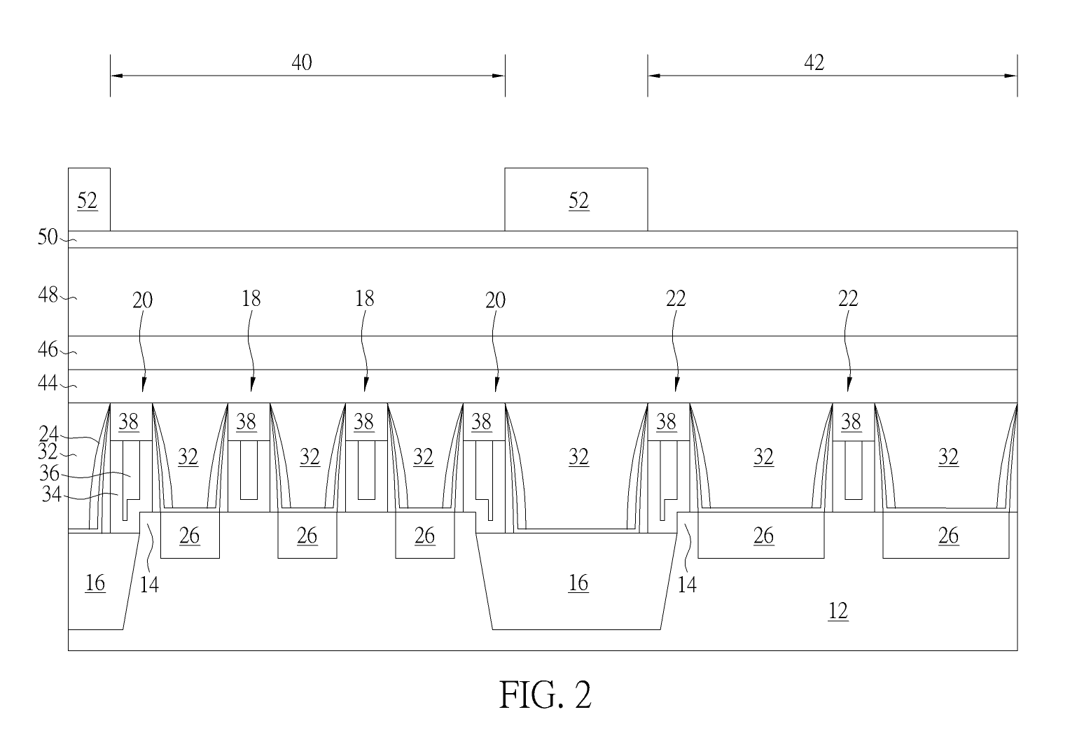

Next, as shown in FIG. 2, an organic dielectric layer (ODL) 48, a silicon-containing hard mask bottom anti-reflective coating (SHB) 50, and a patterned mask 52 are formed on the mask layer 46, in which the patterned mask 52 could be a patterned resist or a patterned mask composed of TiN, and the patterned mask 52 is preferably disposed between the first region 40 and the second region 42.

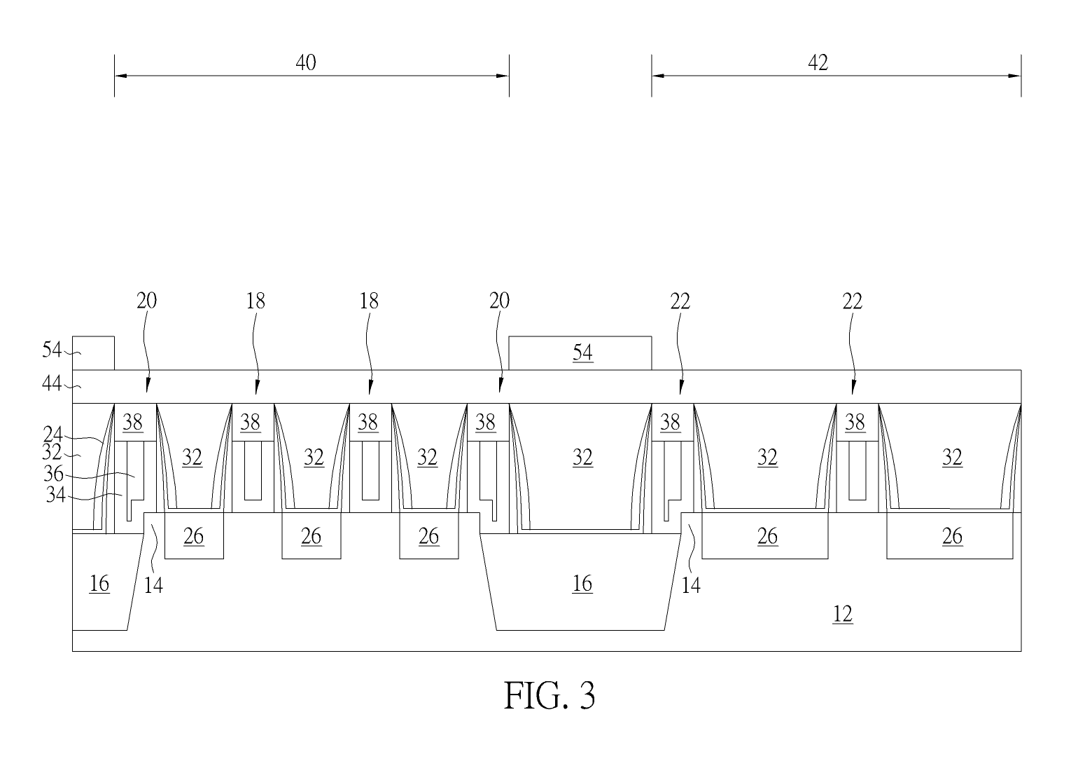

Next, as shown in FIG. 3, an etching process is conducted by using the patterned mask 52 as mask to remove part of the SHB 50, part of the ODL 48, and part of the mask layer 46, and the patterned mask 52, remaining SHB 50, and remaining ODL 48 are then removed to form a patterned mask 54 on the cap layer 44.

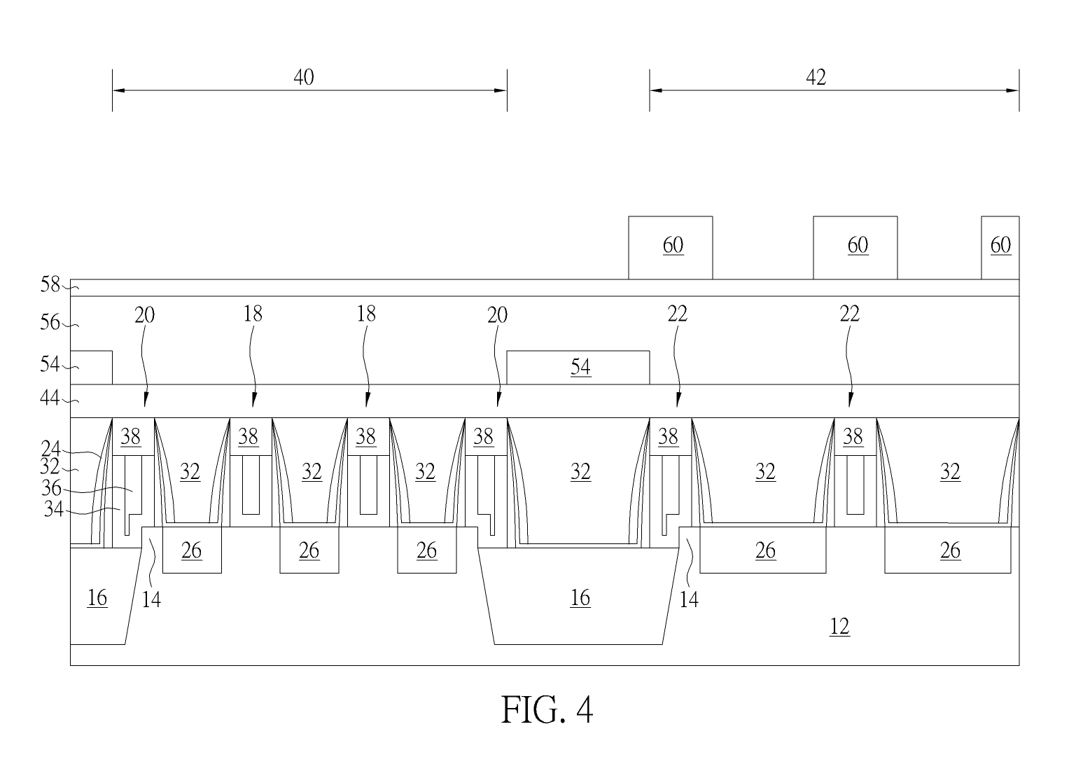

Next, as shown in FIG. 4, another ODL 56, another SHB 58, and another patterned mask 60 are formed on the cap layer 44 and patterned mask 54, in which the patterned mask 60 could be a patterned resist or a patterned mask composed of TiN, and the patterned mask 60 is preferably disposed on the second region 42 to expose all of the SHB 58 on first region 40 and part of the SHB 58 on second region 42.

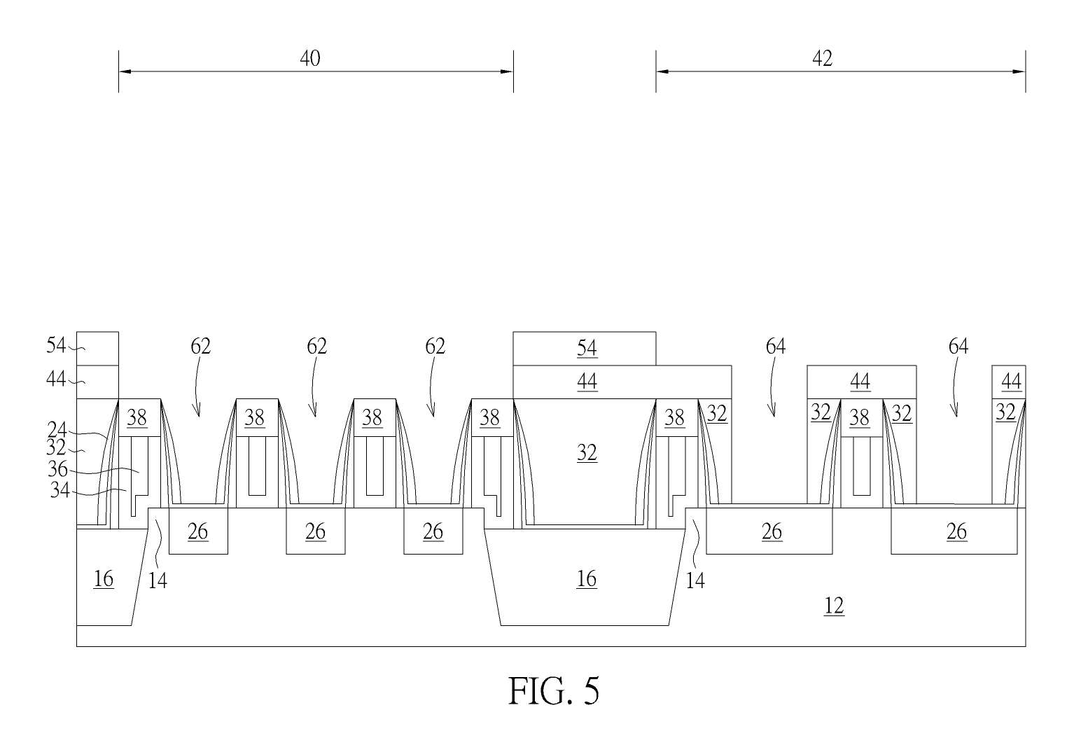

Next, as shown in FIG. 5, an etching process is conducted by using the patterned mask 60 and the patterned mask 54 formed in FIG. 3 as mask to remove part of the SHB 58, part of the ODL 56, part of the cap layer 44, and part of the ILD layer 32 not covered by the patterned mask 60 and patterned mask 54 for forming a plurality of contact holes 62 and 64. The patterned mask 60, remaining SHB 58, and remaining ODL 56 are removed thereafter. It should be noted that since the patterned mask 60 and patterned mask 54 cover part of the second region 42 but expose all of the first region 40 while the gate structures 18, 20 and spacer 24 were used to conduct a self-aligned contact hole process, all of the ILD layer 32 on first region 40 is preferably removed by etching process to form contact holes 62 while only part of the ILD layer 32 on second region 42 is removed by etching process to form contact holes 64 in the ILD layer 32 of second region 42. As a result, no ILD layer 32 is left between the gate structures 18 and 20 on first region 40 while some ILD layer 32 is left between the gate structures 22 on second region 42.

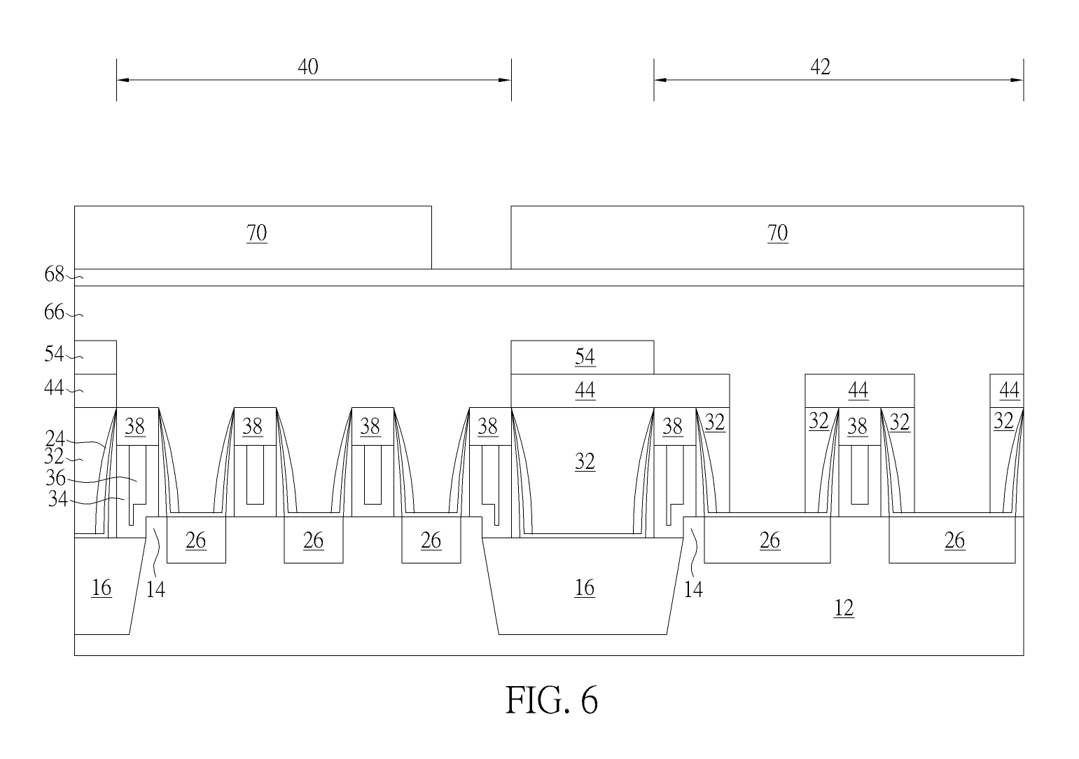

Next, as shown in FIG. 6, another ODL 66, another SHB 68, and another patterned mask 70 are formed on the gate structures 18, 20, 22, ILD layer 32, patterned mask 54, and cap layer 44 and filled into the contact holes 62 and 64, in which the patterned mask 70 could be a patterned resist or a patterned mask composed of TiN.

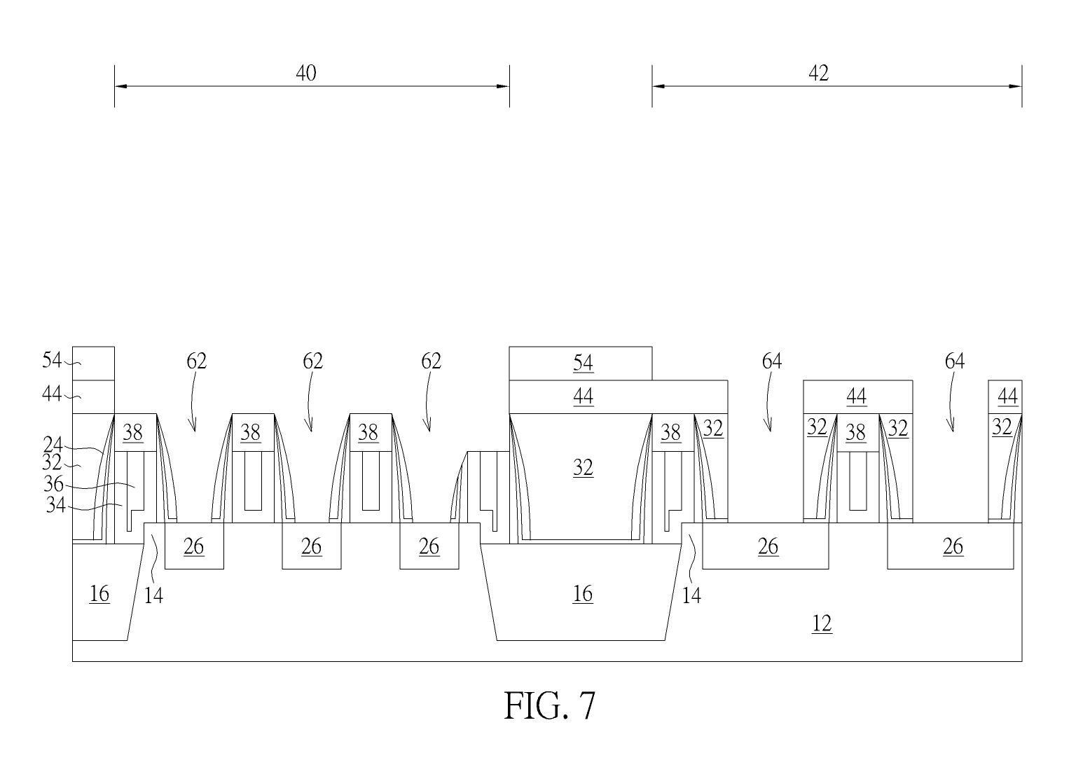

Next, as shown in FIG. 7, an etching process is conducted by using the patterned mask 70 as mask to remove part of the SHB 68, part of the ODL 66, and part of the gate structure 20 on the right edge of fin-shaped structure 14 not covered by the patterned mask 70 on the first region 40 for exposing the electrode surface of the gate structure 20, such as the work function metal layer 34 and low resistance metal layer 36 of gate structure 20. The patterned mask 70, remaining SHB 68, and remaining ODL 66 are removed thereafter.

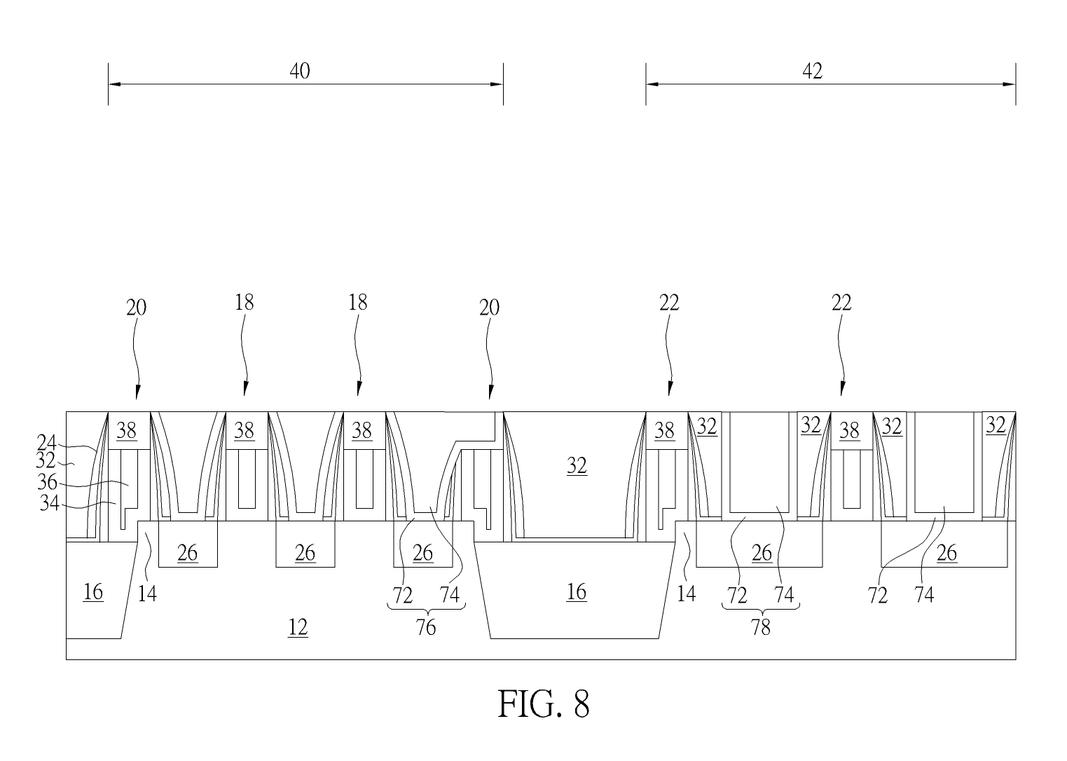

Next, as shown in FIG. 8, a contact plug formation process is conducted by first depositing a barrier layer 72 and a metal layer 74 composed of low resistance material on the gate structures 18, 20, 22, ILD layer 32, patterned mask 54, and cap layer 44 while filling the contact holes 62 and 64 on first region 40 and second region 42. Next, a CMP process is conducted by using the hard mask 38 as stop layer to remove part of the metal layer 74, part of the barrier layer 72, patterned mask 54, and cap layer 44 to form a plurality of contact plugs 76 and 78 on the first region 40 and second region 42. In this embodiment, the barrier layer 72 could be selected from the group consisting of Ti, TiN, Ta, and TaN, and the metal layer 74 could be selected from the group consisting of W, Cu, Al, TiAl, and CoWP.

Viewing from the structure shown in FIG. 8, the semiconductor device preferably includes a plurality of gate structures 18 and 20 on the fin-shaped structure 14 on first region 40, a plurality of gate structures 22 on the fin-shaped structure 14 on second region 42, a plurality of contact plugs 76 between the gate structures 18 and 20 on first region 40 and a plurality of contact plugs 78 between the gate structures 22 on second region 42. In this embodiment, since no ILD layer 32 is formed between the gate structures 18 and 20 on first region 40, the contact plugs 76 on the first region 40 are disposed not only between the gate structures 18 and 20 but also contacting the spacers 24 adjacent to the gate structures 18 and 20 directly. Since an ILD layer 32 is disposed between the gate structures 22 on second region 42, the contact plugs 78 on the second region 42 not only disposed between the gate structures 22 but also contacting the ILD layer 32 directly.

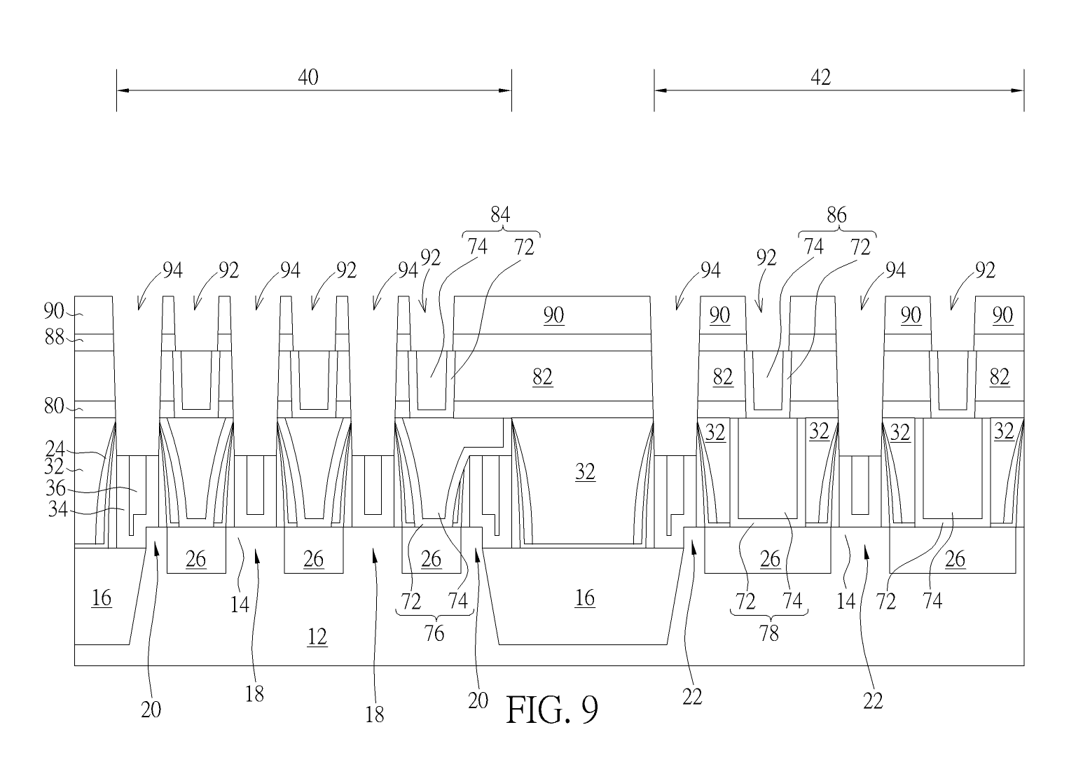

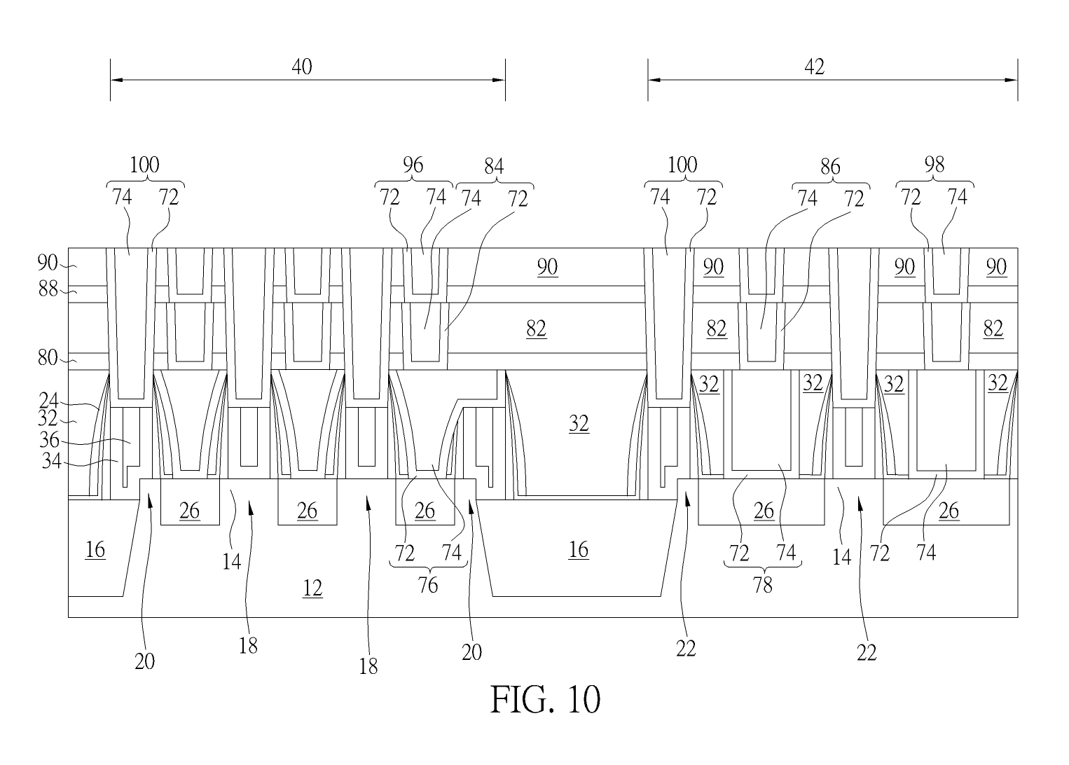

Referring to FIGS. 9-10, FIGS. 9-10 illustrate a method of forming multiple dielectric layers and contact plugs on the contact plugs 76 and 78 after the formation of contact plugs 76 and 78 in FIG. 8. As shown in FIG. 9, a stop layer 80 and a dielectric layer 82 are formed on the ILD layer 32 and contact plugs 76 and 78, and a photo-etching process is conducted to remove part of the dielectric layer 82 and stop layer 80 to form contact holes (not shown) exposing the contact plugs 76 and 78. Next, the contact plug formation conducted in FIG. 8 is carried out to form barrier layer 72 and metal layer 74 in the contact holes and a CMP process is conducted to form contact plugs 84 and 86 directly on top of the contact plugs 76 and 78.

Next, a stop layer 88 and a dielectric layer 90 are deposited on the dielectric layer 82, and one or more photo-etching processes are conducted to remove part of the dielectric layer 90, part of the stop layer 88, part of the dielectric layer 82, part of the stop layer 80, and the hard mask 38 to form contact holes 92 exposing the contact plugs 84 and 86 and contact holes 94 exposing the gate electrode or work function metal layer 34 and low resistance metal layer 36 of gate structures 18, 20, 22.

Next, as shown in FIG. 10, contact plug formation conducted in FIG. 8 is carried out to form barrier layer 72 and metal layer 74 in the contact holes 92 and 94, and a CMP process is conducted to form contact plugs 96 and 98 directly above the contact plugs 84 and 86 and contact plugs 100 electrically connected to the gate structures 18, 20, 22. This completes the fabrication of a semiconductor device according to another embodiment of the present invention.

Viewing from the structure shown in the first region 40 of FIG. 10, the semiconductor device preferably includes a plurality of gate structures 18 and 20 on the fin-shaped structure 14, an ILD layer 32 surrounding the gate structures 18 and 20, a plurality of contact plugs 76 in the ILD layer 32 and between gate structures 18 and 20, a dielectric layer 82 on the gate structures 18, 20 and the ILD layer 32, a stop layer 80 between the dielectric layer 82 and ILD layer 32, a plurality of contact plugs 84 in the dielectric layer 82 and contacting the contact plugs 76, a dielectric layer 90 on the dielectric layer 82, another stop layer 88 between the dielectric layer 90 and dielectric layer 82, a plurality of contact plugs 96 in the dielectric layer 90 and contacting the contact plugs 84, and a contact plug 100 in the dielectric layers 90 and 82 and electrically connected to the gate structures 18 and 20.

Overall, the present invention discloses a triple layered contact plug structures, in which three contact plugs 76, 84, 96 are formed in the ILD layer 32, dielectric layer 82, and dielectric layer 90 and disposed directly on top of the source/drain region 26 while the three contact plugs 76, 84, and 96 contact each other. A single contact plug 100 is disposed directly on top of each of the gate structures 18 and 20, and the top surface of the contact plugs 96 on topmost layer above the source/drain region 26 is even with the top surface of the contact plugs 100 above the gate structure 18 and 20.

It should be noted that in contrast to the contact plug formed by conventional dual damascene process having trench conductor and via conductor, the contact plugs 76, 84, 96, 100 of the present invention are not fabricated by dual damascene processes, hence each of the contact plugs 76, 84, 96, 100 only contains one single conductor, such as either a trench conductor or a via conductor from typical dual damascene structure. In addition, each of the contact plugs 76, 84, 96, 100 of the aforementioned embodiments preferably includes a U-shaped barrier layer 72 and a metal layer 74 formed atop, in which the top surface of the U-shaped barrier layers 72 and the top surface of the metal layers 74 in the contact plugs 76, 84, 96, 100 are coplanar.

Moreover, gate structures 20 are formed on both left edge and right edge of the fin-shaped structure 14 on first region 40, in which a contact plug 76 disposed on top of the gate structure 20 on the right edge of fin-shaped structure 14 is electrically connected to and contacting the gate structure 20 and the source/drain region 26 at the same time while two more contact plugs 84 and 96 are disposed directly on top of the contact plug 76. In other words, in contrast to only one single contact plug 100 is electrically connected to each of the three gate structures 18 and 20 on the left on first region 40, three contact plugs 76, 84, 96 are electrically connected to the gate structure 20 on the right on first region 40.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate having a first fin-shaped structure on a first region and a second fin-shaped structure on a second region;
forming a plurality of first gate structures on the first fin-shaped structure, a plurality of second gate structures on the second fin-shaped structure, and an interlayer dielectric (ILD) layer around the first gate structures and the second gate structures;
forming a first patterned mask on the ILD layer and between the first region and the second region;
forming a second patterned mask on the second region; and
using the first patterned mask and the second patterned mask to remove all of the ILD layer from the first region and part of the ILD layer from the second region for forming a plurality of first contact holes in the first region and a plurality of second contact holes in the second region.

2. The method of claim 1, further comprising forming a cap layer on the first gate structures, the second gate structures, and the ILD layer before forming the first patterned mask.

3. The method of claim 2, further comprising using the first patterned mask and the second patterned mask to remove part of the cap layer before removing all of the ILD layer from the first region and part of the ILD layer from the second region.

4. The method of claim 1, wherein the first patterned mask comprises TiN.

5. The method of claim 1, wherein a third gate structure on an edge of the first fin-shaped structure, the method further comprises using a third patterned mask to remove part of the third gate structure.

6. The method of claim 5, further comprising forming:
forming a metal layer in the first contact holes and the second contact holes and on the first patterned mask and the ILD layer; and
removing part of the metal layer and the first patterned mask for forming a plurality of first contact plugs in the first region and a plurality of second contact plugs in the second region.

7. A semiconductor device, comprising:
a substrate having a first region and a second region;
a first fin-shaped structure on the substrate and a second fin-shaped structure on the second region;
a plurality of first gate structures on the first fin-shaped structure, wherein the first gate structures comprise no interlayer dielectric (ILD) layer therebetween; and
a plurality of second gate structures on the second fin-shaped structure, wherein the second gate structures comprise a ILD layer therebetween.

8. The semiconductor device of claim 7, further comprising a spacer adjacent to each of the first gate structure and a plurality of first contact plugs between the first gate structures and contacting the spacer directly.

9. The semiconductor device of claim 7, further comprising a plurality of second contact plugs adjacent to the second gate structures, wherein the second contact plugs contact the ILD layer directly.

10. A semiconductor device, comprising:
a substrate having a fin-shaped structure thereon;
a plurality of first gate structures on the fin-shaped structure and an interlayer dielectric (ILD) layer around the first gate structures;
a first contact plug in the ILD layer adjacent to the first gate structures;
a first dielectric layer on the ILD layer;
a second contact plug in the first dielectric layer and contacting the first contact plug;
a second dielectric layer on the first dielectric layer;
a third contact plug in the second dielectric layer and contacting the second contact plug; and
a fourth contact plug in the second dielectric layer and the first dielectric layer and electrically connected to one of the first gate structures.

11. The semiconductor device of claim 10, further comprising:
a first stop layer between the ILD layer and the first dielectric layer; and
a second stop layer between the first dielectric layer and the second dielectric layer.

12. The semiconductor device of claim 10, wherein the second contact plug and the third contact plug are directly on top of the first contact plug.

13. The semiconductor device of claim 10, wherein each of the first contact plug, the second contact plug, the third contact plug, and the fourth contact plug comprises a U-shaped barrier layer.

14. The semiconductor device of claim 10, further comprising a second gate structure on an edge of the fin-shaped structure and a shallow trench isolation (STI).
